(19) United States
(12) Patent Application Publication
(10) Pub. No.: US 2014/0191393 A1
(43) Pub. Date: Jul. 10, 2014

(54) SEMICONDUCTOR PACKAGE AND FABRICATION METHOD THEREOF

(71) Applicant: Siliconware Precision Industries Co., Ltd, Taichung (TW)

(72) Inventors: Lung-Tang Hung, Taichung (TW); Wei-Sheng Lin, Taichung (TW); Meng-Hung Yeh, Taichung (TW)

(73) Assignee: SILICONWARE PRECISION INDUSTRIES CO., LTD, Taichung (TW)

(21) Appl. No.: 14/086,599

(22) Filed: Nov. 21, 2013

(30) Foreign Application Priority Data
Jan. 7, 2013 (TW) 102100385

(51) Int. Cl. H01L 23/00

(52) U.S. Cl. CPC H01L 24/14; H01L 24/46; H01L 24/97
USPC 257/737; 257/741; 438/124

(57) ABSTRACT

A semiconductor package is provided, including a carrier having electrical connecting pads, a semiconductor element disposed on the carrier and having electrode pads, conductive elements electrically connected to the electrode pads and the electrical connecting pads, fluorine ions formed between the conductive elements and the electrode pads or between the conductive elements and the electrical connecting pads, and an encapsulant formed on the carrier and the conductive elements, wherein the electrode pads or the electrical connecting pads are formed by aluminum materials to form fluorine aluminum by way of packaging the fluorine ions after the completion of the packaging process. Accordingly, the corrosion resistance of the semiconductor package is increased.

### BACKGROUND OF THE INVENTION

1. Field of the Invention

This invention relates to semiconductor packages and fabrication methods thereof, and, more particularly, to a semiconductor package having a semiconductor chip mounted on a carrier and a method of fabricating the same.

2. Description of Related Art

With the flourishing of electronic industry, electronic products gradually become multiple-function and high-performance. As shown in FIG. 1A, disclosed is a conventional wire bonding semiconductor package 1 in which a semiconductor chip 11 having a plurality of electrode pads 110 is mounted on a carrier 10, such as a leadframe and a packaging substrate. Then the semiconductor chip 11 is electrically connected with electrical connecting pads of the carrier (or a guide foot of the leadframe) by bonding wires 12. The semiconductor chip 11 and wire 12 are encapsulated by an encapsulant such as an epoxy resin. Thus the semiconductor chip 11 and carrier 10 are protected from the moisture or contamination in the environment via the encapsulant 13.

In the prior art semiconductor package 1, the encapsulant 13 has fluorine (Cl) ions 130 as shown in FIG. 1B, and the bonding wires 12 are copper (Cu) wires.

Moreover, in comparison with gold (Au) wires, using copper wires as the bonding wires 12 can not only save the cost but also achieve better electrical and thermal conductivities such that the copper wire has a smaller diameter and a better heat-dissipating efficiency.

Furthermore, after the prior art semiconductor package 1 is fabricated, as shown in FIG. 1B(a), by the reaction between an aluminum (Al) material 14a (material of the electrical connecting pad 100 and electrode pad 110) and a copper material 14b (material of the electrical wire 12), an aluminum-copper alloy compound 15 is generated as a conventional intermetallic compound (IMC) as shown in the chemical formula (1) below. The aluminum/copper alloy compound 15 is classified by ingredients into a first alloy portion 15a and a second alloy portion 15b. That is, the first alloy portion 15a has more aluminum (because it is closer to the aluminum material 14a), and the second alloy portion 15b has more copper (because it is closer to the copper material 14b).

9Cu+4Al→Cu₉Al₄ (1)

Afterward, as shown in FIG. 1B(b), chlorine ions 130 of the encapsulant 13 corrode the aluminum/copper alloy compound 15, and cause the second alloy portion 15b and the chlorine ions 130 to generate an aluminum chloride (AlCl₃) layer 16 and copper ions 140 as shown in the chemical formula 2 below. Moreover, hydroxyl radicals are generated in a moisture environment (such as in a pressure cooker), as shown in the chemical formula (3) below, so the hydroxyl radicals have a chemical reaction with the aluminum chloride layer 16 to generate an alumina (Al₂O₃) layer 17 and acid substances. As shown in FIG. 1B(c) and the chemical formula (4) below.

Cu₉Al₄+12Cl⁻→4AlCl₃+9Cu+12e⁻ (2)

H₂O+1/2O₂+2e⁻→2OH⁻ (3)

AlCl₃+3OH⁻→Al₂O₃+3HCL+3e⁻ (4)

However, alumina (Al₂O₃) is an insulated substance, which has a bad corrosion resistance. That is, the alumina layer 17 is easily corroded so that the corrosion rate of the alumina layer increases, which causes the copper wire (the copper material 14b or wire 12) to detach, so the semiconductor package 1 is electrically disconnected and results a bad reliability of the product.

Therefore, how to overcome the mentioned problems of the prior art is substantially an issue desirably to be solved.

### SUMMARY OF THE INVENTION

In view of the above-mentioned problems of the prior art, the objective of this invention is to provide a semiconductor package, comprising: a carrier having a plurality of electrical connecting pads; a semiconductor element disposed on the carrier and having a plurality of electrode pads, and the electrode pads and the electrical connecting pads are formed by aluminum material; a plurality of conductive elements electrically connected to the electrode pads and the electrical connecting pads; fluorine ions formed between the conductive elements and the electrode pads or between the conductive elements and the electrical connecting pads; and an encapsulant formed on the carrier and conductive elements.

In the foresaid semiconductor package, the conductive elements are copper wires or copper lumps.

This invention further provides a fabrication method of semiconductor package, comprising: disposing at least a semiconductor element having a plurality of electrode pads is disposed on a carrier having a plurality of electrical connecting pads, wherein the electrode pads and the electrical connecting pads are formed by aluminum material; forming fluorine ions on the electrode pads or electrical connecting pads; electrically connecting the electrode pads and the electrical connecting pads via a plurality of conductive elements; and forming an encapsulant on the carrier and conductive elements.

In the foresaid fabrication method, the conductive elements are copper wires.

This invention further provides a fabrication method of semiconductor package, comprising: the disposing at least a semiconductor element on a carrier via a plurality of conductive elements, wherein the carrier is formed with a plurality of electrical connecting pads, the at least a semiconductor element is formed with a plurality of electrode pads, the electrode pads and the electrical connecting pads are formed by aluminum material, fluorine ions are further formed on the electrode pads or electrical connecting pads, and the conductive elements are electrically connected to the electrode pads and the electrical connecting pads; and an encapsulant is formed on the carrier and conductive elements.

In the foresaid fabrication method, the conductive elements are copper lumps.

The foresaid two fabrication methods further comprise cleaning the electrode pads and the electrical connecting pads by an organic fluorine solvents, and a trace of fluorine ions in the organic fluorine solvent are attached to remain on the electrode pads and electrical connecting pads to form the fluorine ions.

In the foresaid semiconductor package and fabrication method thereof, an intermetallic compound is formed between the conductive elements and the electrode pads and between the conductive elements and the electrical connecting pads.

In the foresaid semiconductor package and fabrication method thereof, the fluorine ions exist in the form of aluminum fluoride, for example, aluminum fluoride is formed between the conductive elements and the electrode pads and between the conductive elements and the electrical connecting pads.

In addition, the foresaid semiconductor package and fabrication method thereof further include forming aluminum chloride on the electrode pads and electrical connecting pads since the encapsulant contains chlorine ions.

Hence, the semiconductor package and fabrication method thereof decrease the aluminum chloride content in the prior art by adding fluorine ions to form aluminum fluoride, so the amount of formed aluminum oxide is reduced. In comparison with the corrosion rate in the prior art, the corrosion rate in this invention is considerably reduced. This invention also improves the efficacy of corrosion resistance to avoid the electrical disconnecting problem caused by detached electrical elements (copper wires or copper lumps). Therefore, this invention can not only improve the reliability of the semiconductor package, but also extend the life of a pressure cooker test.

### BRIEF DESCRIPTION OF DRAWINGS

The invention can be more fully understood by reading the following detailed description of the preferred embodiments, with reference made to the accompanying drawings, wherein:

FIG. 1A is a schematic sectional view of a prior semiconductor package;

FIG. 1B is a reaction flow diagram of a prior semiconductor package;

FIGS. 2A-2C are schematic sectional views for the first embodiments of a fabrication method of semiconductor package in this invention;

FIG. 2D is a reaction flow diagram of a semiconductor package in this invention; and

FIGS. 3A-3B are schematic sectional views for the second embodiments of a fabrication method of semiconductor package in this invention.

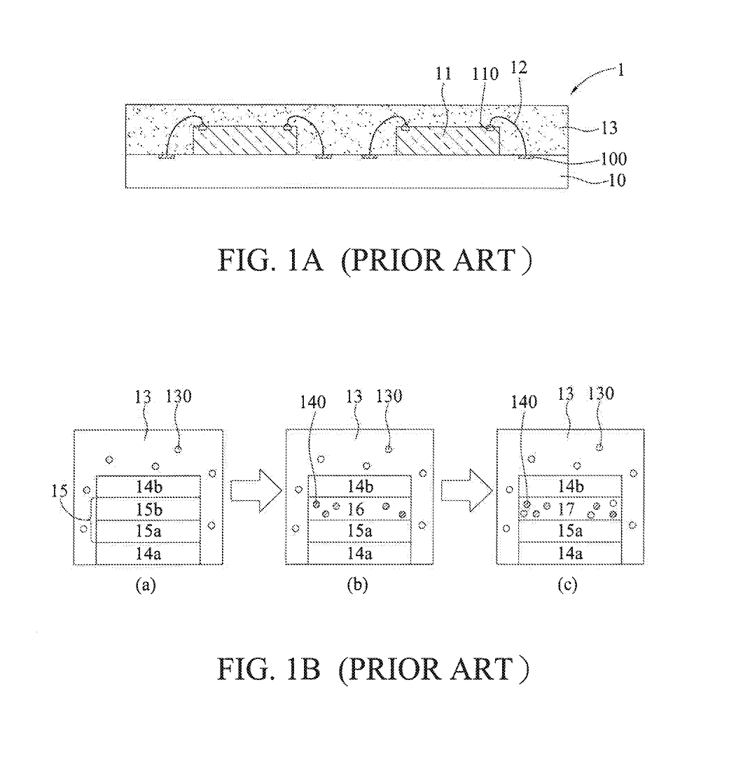

### DETAILED DESCRIPTION OF THE INVENTION

The following illustrative embodiments are provided to illustrate the disclosure of the present invention, these and other advantages and effects can be apparently understood by those in the art after reading the disclosure of this specification. The present invention can also he performed or applied by other different embodiments. The details of the specification may be on the basis of different points and applications, and numerous modifications and variations can be devised without departing from the spirit of the present invention.

It should be advised that the structure, ratio, and size as illustrated in this context are only used for disclosures of this specification, provided for persons skilled in the art to understand and read, and technically do not have substantial meaning. Any modification of the structure, change of the ratio relation, or adjustment of the size should be involved in the scope of disclosures in this specification without influencing the producible efficacy and the achievable objective of this specification. Also, the referred terms such as “on” and “one” in this specification are only for the convenience to describe, not for limiting the scope of embodiment in this invention. Those changes or adjustments of relative relationship without substantial change of technical content should also be considered within the category of implementation.

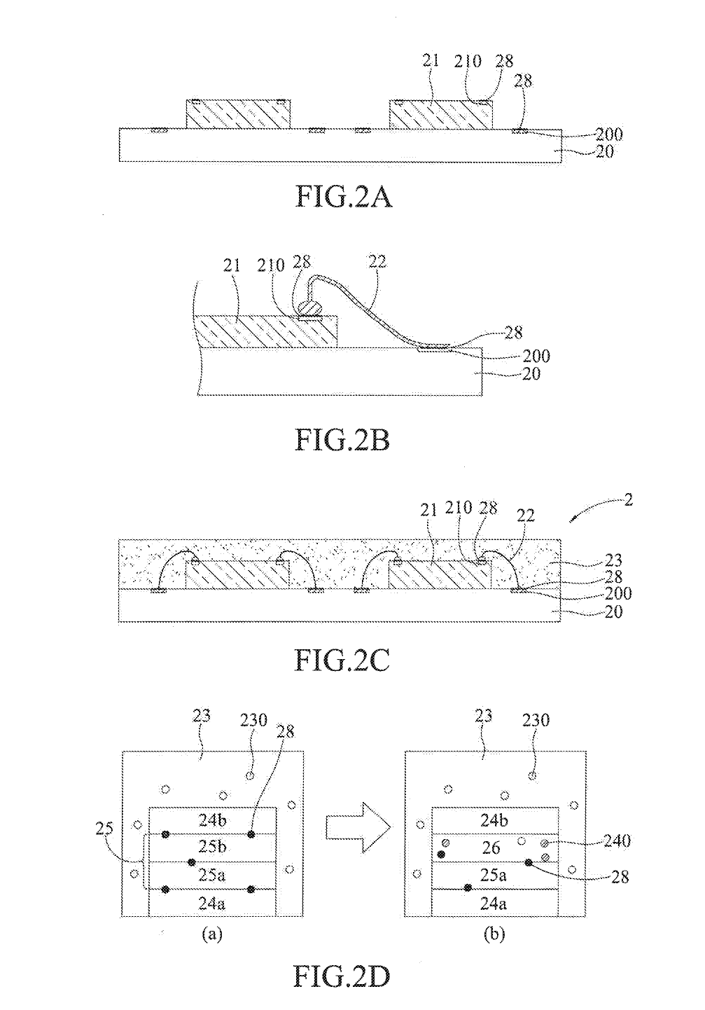

FIGS. 2A-2C are schematic sectional views for the first embodiments of a fabrication method of a semiconductor package 2 in this invention.

As shown in FIG. 2A, a semiconductor element 21 having a plurality of electrode pads 210 is disposed on the carrier 20 having a plurality of electrical connecting pads 200, and fluorine (F) ions 28 are formed on the electrode pads 210 and electrical connecting pads 200.

In this embodiment, the carrier 20 is a packaging substrate, and the electrode pads and the electrical connecting pads are formed by aluminum (Al) material. In another embodiment, the material of the electrode pads 210 may be other metal material, only the material of the electrical connecting pads 200 is aluminum (Al) material; optionally, only the material of the electrode pads 210 is aluminum (Al) material, and the material of the electrical connecting pads 200 is other metal material.

Moreover, in other embodiments, the carrier 20 may also be a leadframe, and the leads of the leadframe are used as the electrical connecting pads 200.

Further, the electrode pads 210 and the electrical connecting pads 200 are cleaned by organic fluorine solvents, and a trace of fluorine ions remain on the electrode pads 210 and the electrical connecting pads 200 to form the above-mentioned fluorine ions 28.

As shown in FIG. 2B, a wire bonding process is performed such that the electrode pads 210 are electrically connected to the electrical connecting pads 200 by a plurality of conductive elements 22.

In this embodiment, the conductive elements 22 are copper (Cu) wire, so the intermetallic compound (IMC) 25 will be formed between the conductive elements 22 and the electrode pads 210 and between the conductive elements and the electrical connecting pads 200 (as shown in FIG. 2D).

As shown in FIGS. 2C and 2D, an encapsulant 23 containing chlorine (Cl) ions 230 is formed on the carrier 20 to encapsulate the semiconductor element 21 and those conductive elements 22.

After the packaging process is completed, as shown in FIG. 2D, by the reaction between an aluminum (Al) material 24a (material of the electrical connecting pad 200 and electrode pad 210) and a copper material 24b (material of the electrical wire 22), an intermetallic compound 25 is generated as an aluminum-copper (Al—Cu) alloy compound as shown in the chemical formula (5) below. The intermetallic compound 25 is classified by ingredients into the first alloy portion 25a and the second alloy portion 25b as shown in FIG. 2D(a). The first alloy portion 25a has more aluminum (because it is closer to the aluminum material 24a), and the second alloy portion 25b has more copper (because it is closer to the copper material 24b).

9Cu+4Al→Cu₉Al₄ (5)

Afterwards, chlorine ions 230 and fluorine ions 28 of the second alloy portion 25b and the capsulant 23 generate copper ions 240 and a compound layer 26 having aluminum chloride (AlCl₃) and aluminum fluoride (AlF₃). As shown in the chemical formula (6) below.

Cu₉Al₄+12(Cl⁻+F⁻)→4(AlCl₃+AlF₃)+9Cu+12e⁻ (6)

Moreover, hydroxyl radicals are generated in a moisture environment (such as a pressure cooker), so the hydroxyl radicals have a chemical reaction with the aluminum chloride to generate alumina (Al₂O₃). On the other hand, because the activity of aluminum fluoride is more stable than that of aluminum chloride and aluminum fluoride is not easily dissolved in water, aluminum fluoride does not oxidize to alumina.

Therefore, the amount of intermedium of the conventional corrosion reaction can be reduced by forming aluminum fluoride. That is to say, reducing the content of aluminum chloride can considerably reduce the amount of the formation of alumina. Preferably, the aluminum chloride is less in content than the aluminum fluoride. Thus, in comparison with the conventional aluminum chloride layer, aluminum fluoride can alleviate the corrosion from moisture to chlorine ions so that the corrosion rate of the compound layer 26 is considerably reduced. Aluminum fluoride can further increase the efficacy of corrosion resistance to avoid the electrical disconnecting problem caused by detached electrical elements 22. Accordingly, the reliability of the semiconductor package 2 is improved and the life of a pressure cooker test is also extended.

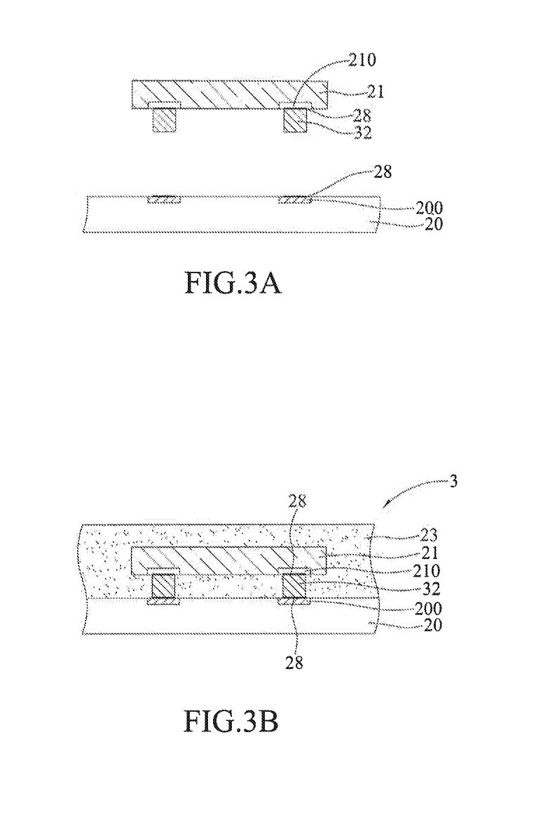

FIGS. 3A-3B are schematic sectional views for the second embodiments of a fabrication method of semiconductor package in this invention. This embodiment differs from the first embodiment mainly in the structure and packaging method of conductive elements 32.

As shown in FIG. 3A, the conductive elements 32 are copper lumps and formed on the electrode pads 210, and fluorine ions are formed on the electrode pads 210 and electrical connecting pads 200.

In other embodiments, the conductive elements 32 may be also formed on the electrical connecting pads 200; or, the conductive elements 32 are formed on the electrical connecting pads 200 and the electrode pads 210.

As shown in FIG. 3B, in a flip-chip way, the semiconductor element 21 is disposed on the carrier 20 via the conductive elements 32, and the conductive elements 32 are electrically connected to the electrode pads 210 and the electrical connecting pads 200.

Subsequently, an encapsulant 23 is formed on the carrier 20 to encapsulate the semiconductor element 21 and those conductive elements 32.

After the packaging process is completed, as shown in FIG. 2D, by the reaction between an aluminum material 24a and a copper material 24b, an intermetallic compound 25 is obtained, and the intermetallic compound 25 is classified by ingredients into the first alloy portion 25a and the second alloy portion 25b. The first alloy portion 25a has more aluminum, and the second alloy portion 25b has more copper. Afterward, chlorine ions 230 and fluorine ions 28 of the second alloy portion 25b and the encapsulant 23 generate copper ions 240 and a compound layer 26 having aluminum chloride and aluminum fluoride.

Because the activity of aluminum fluoride is more stable than that of aluminum chloride and aluminum fluoride is not easily dissolved in water, aluminum fluoride does not oxidize to alumina. Therefore, the content of aluminum chloride can be reduced by forming aluminum fluoride such that the amount of the formation of alumina can thus be considerably reduced. The corrosion rate of the compound layer 26 is considerably reduced as well. Forming aluminum fluoride can further increase the efficacy of corrosion resistance to avoid the electrical disconnecting problem, and not only improve the reliability of products, but also extend the life of a pressure cooker test for copper lumps.

In addition, there are various methods for flip-chip packaging, which are not limited by foresaid description, hereby stated.

This invention provides a semiconductor package 2 and 3 having a carrier 20 having a plurality of electrical connecting pads 200; at least one semiconductor element 21 disposed on the carrier 20; a plurality of conductive elements 22 and 23 electrically connecting the electrical connecting pads 200 to the semiconductor element 21; fluorine ions 28 formed between the conductive elements 22 and 23 and the electrical connecting pads 200; and an encapsulant 23 formed on the carrier 20 and conductive elements 22 and 32.

In the aforementioned carrier 20, the electrical connecting pads 200 are formed by aluminum materials.

The aforementioned semiconductor element 21 is formed with a plurality of electrode pads 210, which are formed by aluminum materials.

The mentioned conductive elements 22 and 23 are electrically connected to the electrode pads 210 and the electrical connecting pads 200. In one embodiment, the conductive elements 22 are copper wires; in another embodiment, the conductive elements 32 are copper lumps. In one embodiment, an intermetallic compound 25, for example, an aluminum/copper alloy compound, is generated between the electrode pads 210 and the electrical connecting pads 200.

The aforementioned fluorine ions 28 are further formed between the conductive elements 22 and 32 and the electrode pads 210, and also exist as aluminum fluoride (AlF₃).

The aforementioned encapsulant 23 encapsulates the semiconductor element 21. In one embodiment, the encapsulant 23 contains fluorine ions 230 causing aluminum chloride (AlCl₃) to form on the electrode pads 210 and electrical connecting pads 200, but the content of aluminum chloride is less than that of aluminum fluoride.

In summary, the semiconductor package and fabrication method thereof mainly add fluoride ions to form aluminum fluoride which is not oxidized into alumina. The content of aluminum chloride can therefore be reduced to effectively decrease the amount of the formation of alumina. Thus the corrosion rate of the intermetallic compound is considerably reduced in a moisture environment such that the efficacy of corrosion resistance is improved to avoid the occurrence of electrical disconnection in the semiconductor package.

The foregoing descriptions of the detailed embodiments are only illustrated to disclose the features and functions of the present invention and not restrictive of the scope of the present invention. It should be understood to those in the art that all modifications and variations according to the spirit and principle in the disclosure of the present invention should fall within the scope of the appended claims.

1. A semiconductor package, comprising:
a carrier having a plurality of electrical connecting pads;
a semiconductor element disposed on the carrier and having a plurality of electrode pads, wherein the electrode pads and the electrical connecting pads are formed by aluminum material;
a plurality of conductive elements electrically connected to the electrode pads and the electrical connecting pads;
fluorine ions formed between the conductive elements and the electrode pads or between the conductive elements and the electrical connecting pads; and
an encapsulant formed on the carrier and the conductive elements.

2. The semiconductor package of claim 1, wherein the conductive elements are copper wires or copper lumps.

3. The semiconductor package of claim 1, wherein an intermetallic compound is formed between the conductive elements and the electrode pads and between the conductive elements and the electrical connecting pads.

4. The semiconductor package of claim 1, wherein the encapsulant contains chlorine ions.

5. The semiconductor package of claim 4, further comprising aluminum chloride, which is formed on the electrode pads and electrical connecting pads.

6. The semiconductor package of claim 1, wherein the fluorine ions exist as aluminum fluoride.

7. A fabrication method of semiconductor package, comprising:
disposing at least a semiconductor element having a plurality of electrode pads on a carrier having a plurality of electrical connecting pads, wherein the electrode pads and the electrical connecting pads are formed by aluminum material;
forming fluorine ions on the electrode pads or electrical connecting pads;
electrically connecting a plurality of conductive elements to the electrode pads and the electrical connecting pads; and
forming an encapsulant on the carrier and conductive elements.

8. The fabrication method of semiconductor package of claim 7, wherein the conductive elements are copper wires.

9. A fabrication method of semiconductor package, comprising the steps of:
disposing at least a semiconductor element on a carrier via a plurality of conductive elements, wherein the carrier has a plurality of electrical connecting pads formed thereon and the at least a semiconductor element has a plurality of electrode pads formed thereon, the electrode pads and the electrical connecting pads are formed by aluminum material, fluorine ions are further formed on the electrode pads or electrical connecting pad, and the conductive elements are electrically connected to the electrode pads and the electrical connecting pads; and
forming an encapsulant on the carrier and conductive elements.

10. The fabrication method of semiconductor package of claim 9, wherein the conductive elements are copper lumps.

11. The fabrication method of semiconductor package of claim 7, wherein an intermetallic compound is formed between the conductive elements and the electrode pads and between the conductive elements and the electrical connecting pads.

12. The fabrication method of semiconductor package of claim 7, further comprising cleaning the electrode pads and the electrical connecting pads by an organic fluorine solvents so as for a trace of fluorine ions in the organic fluorine solvent which remains on the electrode pads and electrical connecting pads to form the fluorine ions.

13. The fabrication method of semiconductor package of claim 7, further comprising forming aluminum fluoride between the conductive elements and the electrode pads and between the conductive elements and the electrical connecting pads.

14. The fabrication method of semiconductor package of claim 7, wherein the encapsulant contains fluorine ions.

15. The fabrication method of semiconductor package of claim 14, further comprising forming aluminum chloride on the electrode pads and electrical connecting pads.

16. The fabrication method of semiconductor package of claim 9, wherein an intermetallic compound is formed between the conductive elements and the electrode pads and between the conductive elements and the electrical connecting pads.

17. The fabrication method of semiconductor package of claim 9, further comprising cleaning the electrode pads and the electrical connecting pads by an organic fluorine solvents so as for a trace of fluorine ions in the organic fluorine solvent which remains on the electrode pads and electrical connecting pads to form the fluorine ions.

18. The fabrication method of semiconductor package of claim 9, further comprising forming aluminum fluoride between the conductive elements and the electrode pads and between the conductive elements and the electrical connecting pads.

19. The fabrication method of semiconductor package of claim 9, wherein the encapsulant contains fluorine ions.
